(19) United States
(12) Patent Application Publication
(10) Pub. No.: US 2006/0175627 A1
(43) Pub. Date: Aug. 10, 2006

(54) Power supply, multi chip module, system in package and non-isolated DC-DC converter

(76) Inventor: Masaki Shiraishi, Hitachinaka (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/347,290

(22) Filed: Feb. 6, 2006

(30) Foreign Application Priority Data
Feb. 8, 2005 (JP) 2005-031587

(51) Int. Cl. H01L 33/00; H01L 29/22

(52) U.S. Cl. 257/99

(57) ABSTRACT

A power supply includes a non-isolated DC-DC converter for use in a power source system having a high side switch and a low side switch, in which HEMT or HFET or gallium nitride device with low capacity and low on-resistance is used for the high side switch and a vertical power MOSFET of silicon device with low on-resistance is used for the low side switch.

### BACKGROUND OF THE INVENTION

The present invention relates to an IC (Integrated Circuit) for switching used in a power circuit, etc., and in particular, to a technique which is effective applied to the enhancement of the power generation efficiency by a non-isolated DC-DC converter.

Recently, as CPU (Central Processor Unit) and MPU (Micro Processor Unit) used in the personal computer and the server, etc. are using lower voltage and larger current, the use of the larger current and the higher frequency are required in the power supply which supplies power to the CPU and the MPU.

Presently, the non-isolated DC-DC converter used mainly in the above mentioned power supply is configured with a high side switch and a low side switch, and for each of these switches. A vertical power MOS-FET (Metal Oxide Semiconductor-Field Effect Transistor) of silicon device is used respectively. The high side switch is a switch for the control of the DC-DC converter, and the low side switch is a switch for the synchronous rectification.

Now, as the recent power supply is using higher frequency, there has occurred the problem that the switching loss increases especially at the high side switch. Therefore, for example in the technique described in JP-A-2002-217416 it is provided a means to reduce the switching loss by using a lateral power MOSFET of silicon device with small feedback capacity for the high side switch.

However, with the above mentioned lateral power MOSFET, there is a problem that the on-resistance increases and the conductive loss increases in comparison with the vertical power MOSFET. According to the study by the present inventor in a device with the dielectric strength of about 30 V used for the CPU of the present personal computer, etc., the on-resistance per unit area of the lateral power MOSFET is about 4 times as large as that of the vertical power MOSFET. As described above, because the trend of the power supply is to use larger current and higher frequency, with the lateral power MOSFET of silicon device with large on-resistance the conductive loss is large and the high efficiency of the system is difficult.

### SUMMARY OF THE INVETION

Therefore, an object of the present invention is to enhance the conversion efficiencies of the non-isolated DC-DC converter and to provide a power supply which can realize high efficiency.

The above mentioned and other objects and new features of the present invention will be apparent from the description of this specification and the accompanied drawings.

The following is the brief description of the outline of the representatives of the inventions disclosed in this application.

The present invention is applied to a power supply comprising a high side switch and a low side switch, a multi-chip module mounting a high side switch and a low side switch on the same package, a system in package mounting a high side switch, a low side switch, and a driver IC which drives both switches on the same package, and a non-isolated DC-DC converter using the multi-chip module or the system in package, respectively, and has features as described below.

(1) The high side switch is a gallium nitride device with low capacity and low on-resistance. This gallium nitride device is a lateral device. Moreover, this lateral device is a junction field effect transistor using two-dimensional electronic gas. Or, the high side switch is a junction field effect transistor.

(2) The low side switch is a silicon device with low on-resistance. This silicon device is a vertical power MOSFET.

The following is the brief description of the effect obtained by the representatives of the inventions disclosed in this application.

In accordance with the present invention, it is possible to reduce the switching loss and the conductive loss to enhance the conversion efficiencies and to realize the high efficiency of the power supply by using a gallium nitride device for the high side switch in the non-isolated DC-DC converter.

Other objects, features and advantages of the invention will become apparent from the following description of the embodiments of the invention taken in conjunction with the accompanying drawings.

### BRIEF DESCRIPTION OF THE DRAWINGS

FIG. 1 is a circuit diagram showing an example of a non-isolated DC-DC converter used in a power supply of the embodiment 1 of the present invention.

FIG. 2A is a sectional view showing an example of a lateral structure of a GaN device used as the high side switch in the non-isolated DC-DC converter of the embodiment 1 of the present invention.

FIG. 2B is a chip plane view showing an example of the lateral structure of the GaN device used as the high side switch in the non-isolated DC-DC converter of the embodiment 1 of the present invention.

FIG. 3A is a sectional view showing an example of a conventional lateral power MOSFET of Si device in comparison with the non-isolated DC-DC converter of the embodiment 1 of the present invention.

FIG. 3B is a chip plan view showing an example of the conventional lateral power MOSFET of Si device in comparison with the non-isolated DC-DC converter of the embodiment 1 of the present invention.

FIG. 4A is a sectional view showing an example of a vertical power MOSFET of Si device used as the low side switch in the non-isolated DC-DC converter of the embodiment 1 of the present invention.

FIG. 4B is a chip plan view showing an example of the vertical power MOSFET of Si device used as the low side switch in the non-isolated DC-DC converter of the embodiment 1 of the present invention.

FIG. 5A is a chip arrangement diagram showing an example of a multi-chip module used in a power supply of the embodiment 2 of the present invention.

FIG. 5B is a package plan view showing an example of the multi-chip module used in the power supply of the embodiment 2 of the present invention.

FIG. 6 is a chip arrangement diagram showing an example of a system in package used in a power supply of the embodiment 3 of the present invention.

FIG. 7 is a diagram showing the comparison of the physical values of each kind of semiconductors of Si, GaAs, 4H—SiC, and GaN as the concept of the present invention.

FIG. 8 is a diagram showing the tendency of the operating frequency and the output current of the DC-DC converter for the CPU power supply, and the dependency of the operating frequency and the output current of the estimated value of the loss when a lateral device of Si and a vertical device of Si are used for the high side switch of the DC-DC converter as the concept of the present invention.

FIG. 9 is a diagram showing the tendency of the operating frequency and the output current of the DC-DC converter for the CPU power supply, and the dependency of the operating frequency and the output current of the estimated value of the loss when a lateral device of GaN and a vertical device of Si are used for the high side switch of the DC-DC converter as the concept of the present invention.

### DETAILED DESCRIPTION OF THE EMBODIMENTS

Hereinafter, the embodiments of the present invention will be described in detail based on the drawings. Here, in all of the drawings to explain the embodiments, in principle the same signs are used for the same components and their duplicated explanations will be omitted.

The concept of the present invention will be described using FIGS. 7-9.

The present invention provides a power supply of high efficiency using a lateral device of gallium nitride device (GaN) with both small feedback capacity and on-resistance, especially HEMT (High Electron Mobility Transistor) or HFET (Hetero-structure Field Effect Transistor) which is a junction field effect transistor using two-dimensional electronic gas for the high side switch of the DC-DC converter.

GaN is a wideband gap semiconductor, as well as silicon carbide (SiC) and diamond, etc., and is receiving much attention as a next generation power device material replacing the silicon (Si).

FIG. 7 shows the comparison of the physical values of each kind of semiconductors of Si, gallium arsenide (GaAs), 4H—SiC, and GaN. GaN has larger band gap, dielectric breakdown field, and saturation electron rate compared with Si, GaAs, and SiC, and has almost the same electron mobility as Si although not reaching GaAs. Therefore, it is expected as a power device material with high dielectric strength, high frequency, and high temperature operation. Also, as GaN can create a hetero junction as well as GaAs, it has an advantage that it can create HEMT or HFET using two-dimensional electron gas which can realize low on-resistance.

As an actual characteristic of the GaN device, in ISPSD' 04 (International Symposium on Power Semiconductor Devices & ICs) pp. 369-372 by S. Yoshida, et al. It is represented the one that has the on-resistance of 2 mΩ/cm² per unit area with the dielectric strength of 100 V using the HFET structure. As the present vertical trench MOSFET using Si has about 1.5 mΩ/cm2 with the dielectric strength of 100 V, the GaN device is reduced to the increase of about 1.3 times of on-resistance in comparison with Si.

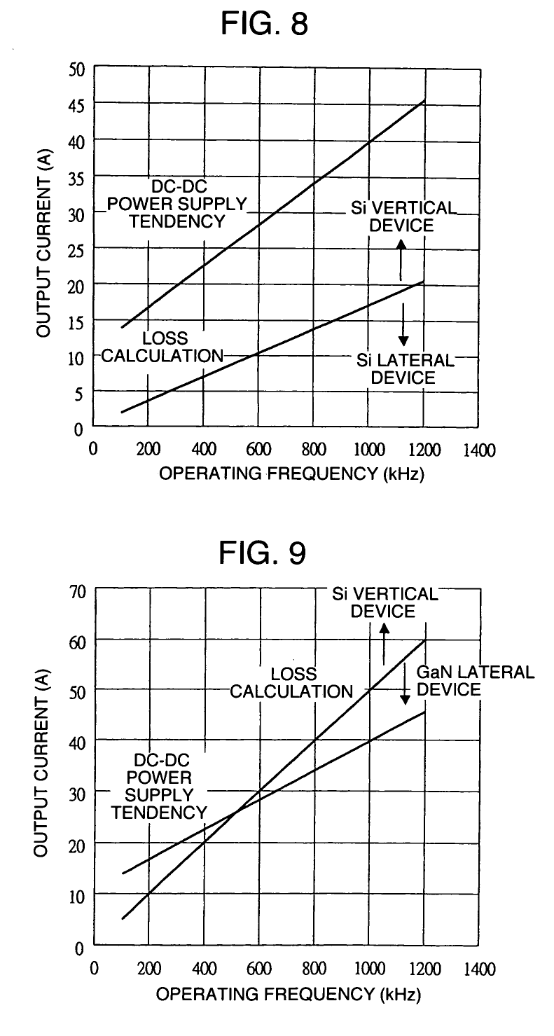

FIG. 8 shows the tendency of the operating frequency and the output current of the DC-DC converter for the CPU power supply, and the dependency of the operating frequency and the output current of the estimated value of the loss when a lateral device of Si and a vertical device of Si are used for the high side switch of the DC-DC converter, that is an estimated value of which can realize the lower loss comparing the cases in which a lateral device of Si and a vertical device of Si are used. The low side switch uses a vertical device of Si. In the upper side area of the loss calculated value of FIG. 8 the one using the vertical device of Si has lower loss, and in the lower side area the one using the lateral device of Si has lower loss. Comparing the trends of the loss calculated value and the DC-DC power supply, it can be seen that using the vertical device of Si the lower loss can be realized. The lateral device of Si can realize the lower loss than the vertical device of Si in the area of high frequency and low current, but is not suited to the usage for the CPU power supply.

FIG. 9, as well as FIG. 8, shows the tendency of the operating frequency and the output current of the DC-DC converter for the CPU power supply, and the dependency of the operating frequency and the output current of the estimated value of the loss when a lateral device of GaN and a vertical device of Si are used for the high side switch of the DC-DC converter, that is an estimated value of which can realize lower loss comparing the cases in which a lateral device of GaN and a vertical device of Si are used. The low side switch uses a vertical device of Si. In the upper side area of the loss calculated value of FIG. 9 the one using the vertical device of Si has lower loss, and in the lower side area the one using the lateral device of GaN has lower loss. With the lateral device of GaN, as the on-resistance is lower compared to the lateral device of Si, although in the larger current area it can have lower loss than the vertical device of Si. Compared to the tendency of the power supply for CPU, in the area in which the operating frequency is about to exceed 500 kHz it can be seen that the lower loss can be realized using the lateral device of GaN rather than using the vertical device of Si. The lateral device of GaN has high on-resistance than that of a vertical device of MOSFET, but can be made a low loss device when the CPU uses a high frequency, and it is effective as the usage for the CPU power supply of high frequency in future.

Then, as an example of the power supply using a lateral device of GaN for the high side switch of the DC-DC converter, an non-isolated DC-DC converter (embodiment 1), a multi-chip module (embodiment 2), and a system in package (embodiment 3) will be specifically described below respectively.

### Embodiment 1

An example of the power supply according to the embodiment 1 of the present invention will be described using the drawings.

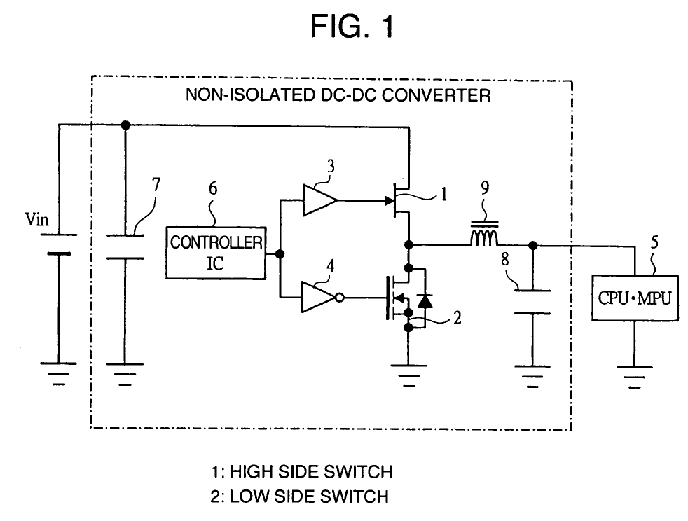

FIG. 1 shows a circuit diagram of an example of the non-isolated DC-DC converter used in the power supply of this embodiment. The non-isolated DC-DC converter of this embodiment is configured with a high side switch 1 which is a GaN device, a low side switch 2 which is a Si device, a driver IC 3 which drives the high side switch 1, a driver IC 4 which drives the low side switch 2, a controller IC 6 which controls the driver IC 3 and IC 4, an input capacitor 7, an output capacitor 8, and an inductor 9, and a DC power supply Vin is connected to the input side and a CPU/MPU 5 is connected to the output side.

In this non-isolated DC-DC converter the power is supplied to the CPU/MPU 5 converting the input DC voltage to the desired DC voltage by driving the high side switch 1 and the low side switch 2 by the driver ICs 3, 4, respectively, by the control of the controller IC 6.

The feature of FIG. 1 is that a GaN device is used for the high side switch 1 and a Si device is used for the low side switch 2, respectively, in different ways. That is, at the high side switch 1 as both the switching loss and the conductive loss occur, the GaN device which is a device with low capacity and certain degree of low on-resistance is used, and at the low side switch 2 as the most of the loss is the conductive loss, the vertical device of Si with small on-resistance is used. As the GaN device whose manufacturing process, etc. have not been established yet and whose cost per chip is expensive, using the Si device in the parts where the Si device can be used, there is also a merit that the increase of cost can be reduced to the minimum.

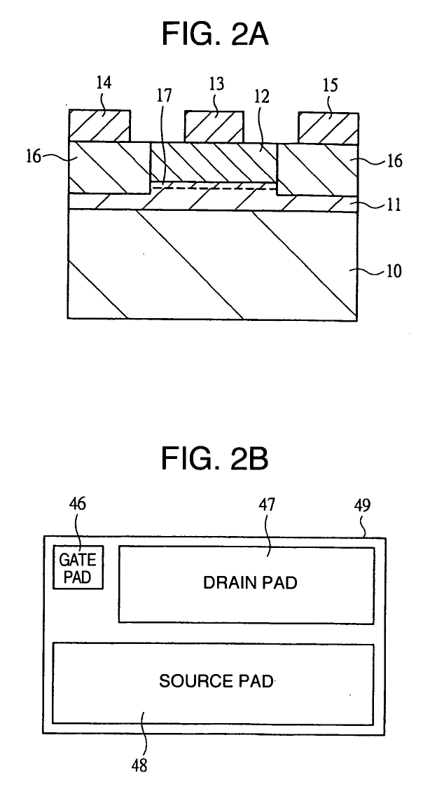

FIGS. 2A and 2B show a sectional view (FIG. 2A) and a chip plan view (FIG. 2B) of an example of a lateral structure of a GaN device used as the high side switch in the non-isolated DC-DC converter of this embodiment. This structure has, as shown in FIG. 2A, semi-insulating GaN layer 11 crystal grown on sapphire or SiC substrate 10, and on that layer thin semi-insulating AlGaN layer 12 is crystal grown, and on that layer gate electrode 13 is formed. Also, to make contact with source electrode 14 and drain electrode 15 n-type GaN layer 16 with doped Si, etc. is formed. Two-dimensional electronic gas layer 17 is formed in the area which is the interface between the GaN layer 11 and the AlGaN layer 12. As a chip plan view, as shown in FIG. 2B, gate pad 46, drain pad 47, and source pad 48 are formed on the chip surface forming GaN device chip 49 of HEMT structure.

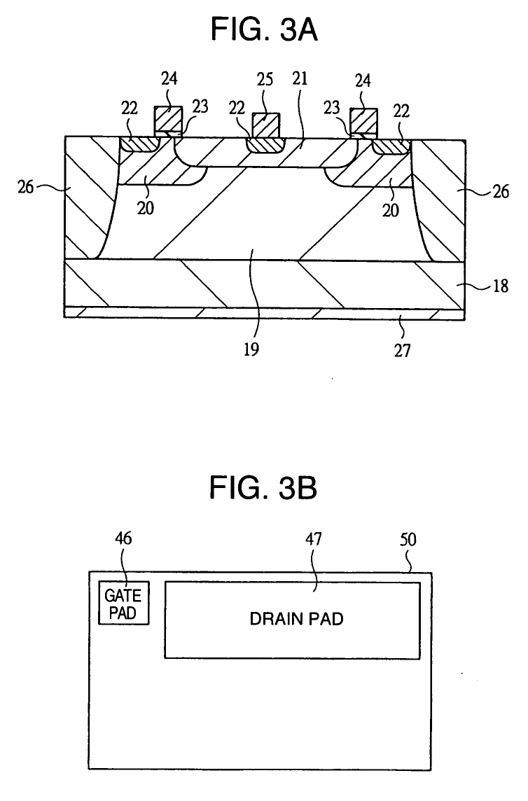

FIGS. 3A and 3B show a sectional view (FIG. 3A) and a chip plan view (FIG. 3B) of an example of a conventional lateral power MOSFET of Si device. This structure, as shown in FIG. 3A, has p⁻ epi-layer 19, channel layer 20, n⁻ drift layer 21, and n⁺ layer 22 on p-type substrate 18, and on the surface gate electrode 24, also drain electrode 25 are formed via gate oxide film 23. Further, it has p⁺ punching layer 26 and source electrode 27 is formed on the back side of the chip. As a chip plane view, as shown in FIG. 3B, gate pad 46 and drain pad 47 are formed on the chip surface forming Si lateral device chip 50. As a feature of the lateral power MOSFET of FIGS. 3A and 3B source pad is not formed on the surface because the source electrode 27 is formed on the back side.

In the structure of FIGS. 3A and 3B it is necessary that the width of the drift layer 21 should be about 2 μm to obtain the dielectric strength of 30 V, therefore the cell size will be bigger and the on-resistance will increase. On the contrary, in the structure of the GaN device of FIGS. 2A and 2B as the insulation breakdown dielectric strength is larger than Si by one figure, the width of the similar drift layer can be reduced to equal to or less than 1/10 and as a result the cell size can be smaller and the low on-resistance is possible.

In the HEMT structure of the GaN of FIGS. 2A and 2B, at the present there has not been reported that a device with the dielectric strength less than about 100 V has been created, but by advancing the micro fabrication of the gate it is possible to create a device with low on-resistance with the dielectric strength of about 30 V.

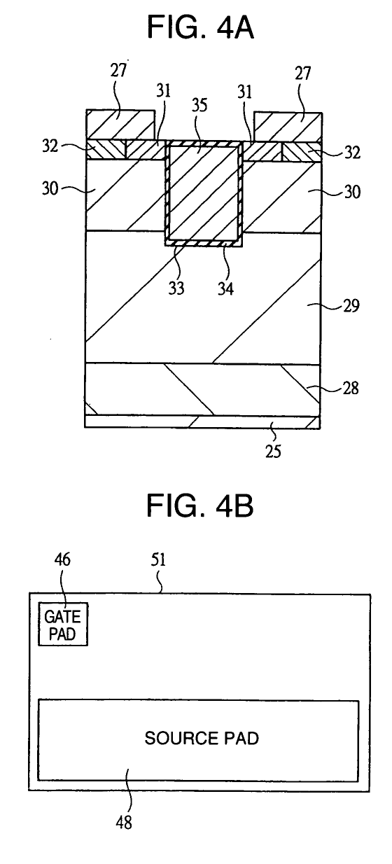

FIGS. 4A and 4B show a sectional view (FIG. 4A) and a chip plane view (FIG. 4B) of an example of a vertical power MOSFET of Si device used as the low side switch in the non-isolated DC-DC converter of this embodiment. In this vertical trench power MOSFET structure, as shown in FIG. 4A, it has n⁻ epi-layer 29, channel layer 30, n⁺ layer 31, and p⁺ layer 32 on n⁺ substrate layer 28, and trench 33 is formed from the surface to the n⁻ epi-layer, and gate electrode 35 is formed via gate oxide film 34. As a chip plan view, as shown in FIG. 4B, gate pad 46 and source pad 48 are formed on the chip surface forming Si vertical device chip 51. In this vertical MOSFET drain pad is not formed on the surface because the drain electrode 25 is formed on the back side.

Therefore, according to this embodiment, it is possible to reduce the switching loss and the conductive loss to enhance the conversion efficiencies of the non-isolated DC-DC converter, and also to realize the high efficiency of the power supply by using the GaN device for the high side switch 1.

### Embodiment 2

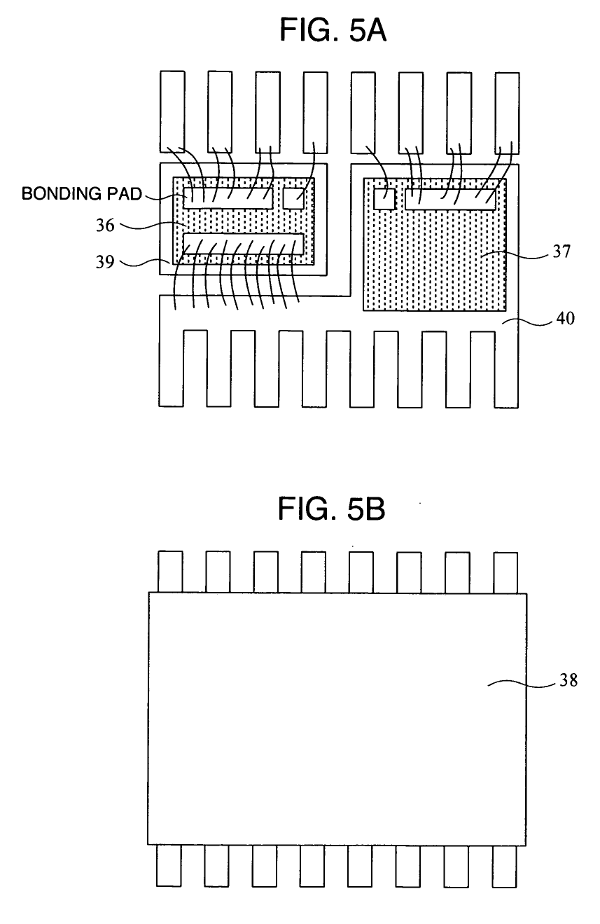

An example of the power supply in the embodiment 2 of the present invention will be described using FIGS. 5A and 5B.

FIGS. 5A and 5B show a chip arrangement diagram (FIG. 5A) and a package plane view (FIG. 5B) of an example of a multi-chip module used in the power supply of this embodiment. The multi-chip module of this embodiment mounts the high side switch 1 and the low side switch 2 which configure the non-isolated DC-DC converter of the above mentioned embodiment 1 on the same package.

That is, the multi-chip module of this embodiment is, as shown in FIG. 5A, configured with high side chip 36 of high side switch and low side chip 37 of low side switch, and the high side chip 36 is mounted on frame 39, the low side chip 37 is mounted on frame 40, and the high side chip 36 and the frame 40 are connected by wire bonding. Afterward, it is completed as a package after experiencing mold encapsulation and so on. As this package, as shown in FIG. 5B, it results in package 38 with only the exterior leads exposed.

Now, in the non-isolated DC-DC converter, it is important for the high efficiency of the power supply to reduce the inductance between the devices. Therefore, in this embodiment, as the parasitic inductance between both switches can be reduced by mounting the high side chip 36 and the low side chip 37 on the same package 38, the high efficiency of the power supply can be realized even more in addition to the effect of the above mentioned embodiment 1.

Further, in this embodiment between the chip and the frame it is connected by wire bonding but it may be connected using metallic board such as Cu for the sake of low inductance and low impedance.

### Embodiment 3

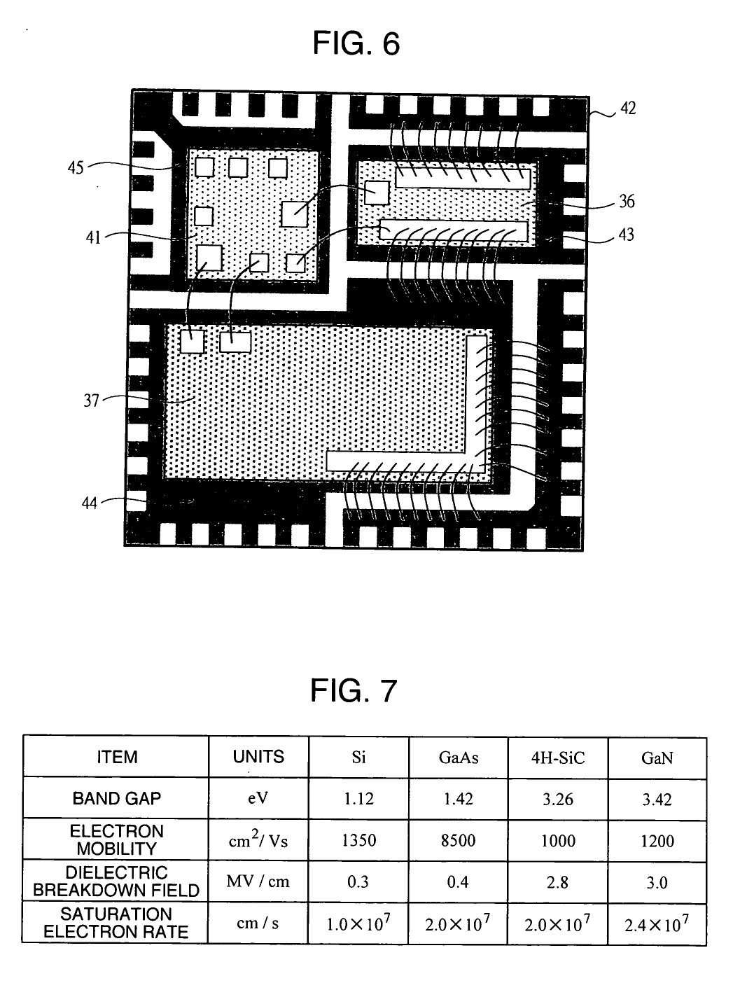

An example of the power supply in the embodiment 3 of the present invention will be described using FIG. 6.

FIG. 6 shows a chip arrangement diagram of an example of a system in package used in the power supply of this embodiment. The system in package of this embodiment mounts the high side switch 1, the low side switch 2, and the driver ICs 3, 4 which configure the non-isolated DC-DC converter of the above mentioned embodiment 1 on the same package.

That is, the system in package of this embodiment is, as shown in FIG. 6, configured with the high side chip 36 of high side switch, the low side chip 37 of low side switch, and driver IC chip 41 of driver IC, and the high side chip 36 is mounted on frame 43, the low side chip 37 is mounted on frame 44, and the driver IC chip 41 is mounted on frame 45. The high side chip 36 and the frame 44, the driver IC chip 41 and the gates of the high side chip 36 and the low side chip 37 are connected by wire bonding respectively. Afterward, it is completed as package 42 after experiencing mold encapsulation and so on.

Therefore, in this embodiment, by mounting also the driver IC chip 41 on the same package 42, in addition to the reducing effect of the parasitic inductance between the high side chip and the low side chip of the above mentioned embodiment 2, the parasitic inductance of the gate is also reduced, the high efficiency of the power supply can be implemented even more. That is, because when the gate parasitic inductance is large it causes the increase of the switching loss and the malfunction, it is also important for the high efficiency of the power supply to reduce the gate inductance.

Above it has been described the present invention made by the present inventor specifically based on the embodiments of the present invention, it is needless to say that the present invention is not limited to the above described embodiments and various amendments are possible without departing from the spirit of the invention.

For example, in the above mentioned embodiments, it was described an example in which a lateral device of GaN, particularly a junction field effect transistor using two-dimensional electronic gas, is used for the high side switch, but the present invention can be applied when a simple junction field effect transistor is used.

The present invention relates to an IC for switching used in a power circuit, etc., and in particular, is effective applied to the enhancement of the power generation efficiency by the DC-DC converter, and more specifically is suited to a non-isolated DC-DC converter, a multi-chip module, and a system in package.

It should be further understood by those skilled in the art that although the foregoing description has been made on embodiments of the invention, the invention is not limited thereto and various changes and modifications may be made without departing from the spirit of the invention and the scope of the appended claims.

1. A power supply comprising a high side switch and a low side switch, wherein the high side switch is a gallium nitride device.

2. A power supply according to claim 1, wherein the gallium nitride device is a lateral device.

3. A power supply according to claim 2, wherein the lateral device is a junction field effect transistor using two-dimensional electronic gas.

4. A power supply according to claim 1, wherein the low side switch is a silicon device.

5. A power supply according to claim 4, wherein the silicon device is a vertical power MOSFET.

6. A multi-chip module mounting a high side switch and a low side switch on the same package, wherein the high side switch is a gallium nitride device.

7. A multi-chip module according to claim 6, wherein the gallium nitride device is a lateral device.

8. A multi-chip module according to claim 7, wherein the lateral device is a junction field effect transistor using two-dimensional electronic gas.

9. A multi-chip module according to claim 6, wherein the low side switch is a silicon device.

10. A multi-chip module according to claim 9, wherein the silicon device is a vertical power MOSFET.

11. A system in package mounting a high side switch, a low side switch, and a driver IC which drives the high side switch and the low side switch on the same package, wherein the high side switch is a gallium nitride device.

12. A system in package according to claim 11, wherein the gallium nitride device is a lateral device.

13. A system in package according to claim 12, wherein the lateral device is a junction field effect transistor using two-dimensional electronic gas.

14. A system in package according to claim 11, wherein the low side switch is a silicon device.

15. A system in package according to claim 14, wherein the silicon device is a vertical power MOSFET.

16. A non-isolated DC-DC converter using the multi-chip module of claim 6.

17. A non-isolated DC-DC converter using the system in package of claim 11.

18. A power supply comprising a high side switch and a low side switch, wherein the high side switch is a junction field effect transistor.

19. A multi-chip module mounting a high side switch and a low side switch on the same package, wherein the high side switch is a junction field effect transistor.

20. A system in package mounting a high side switch, a low side switch, and a driver IC which drives the high side switch and the low side switch on the same package, wherein the high side switch is a junction field effect transistor.
